(19) United States
(12) Patent Application Publication
(10) Pub. No.: US 2026/0190693 A1
(43) Pub. Date: Jul. 2, 2026

(54) Display Device

(71) Applicant: LG Display Co., Ltd., Seoul (KR)

(72) Inventors: Bokyoung Lee, Paju-si (KR); DongKyu Lee, Paju-si (KR)

(21) Appl. No.: 19/317,547

(22) Filed: Sep. 3, 2025

(30) Foreign Application Priority Data
Dec. 27, 2024 (KR) 10-2024-0197998

(51) Int. Cl. H10K 59/131; H10K 59/95

(52) U.S. Cl. CPC H10K 59/131; H10K 59/95

(57) ABSTRACT

A display device may include a display panel including a pad area in which a plurality of bonding pads are formed in a non-display area, and a driving circuit including a plurality of bumps electrically coupled to the plurality of bonding pads in the non-display area. The plurality of bonding pads and the plurality of bumps may include a first pad-bump assembly including a first bonding pad and a first bump disposed to fit one end of the first bonding pad, and a second pad-bump assembly including a second bonding pad and a second bump disposed at the center of the second bonding pad. The first pad-bump assembly and the second pad-bump assembly may be alternately arranged in a first direction and a second direction.

### CROSS REFERENCE TO RELATED APPLICATION

This application claims priority from Republic of Korea Patent Application No. 10-2024-0197998, filed on Dec. 27, 2024, which is hereby incorporated by reference in its entirety.

### TECHNICAL FIELD

Embodiments of the present disclosure relate to a display device, and more specifically, to a display device capable of reducing pad defects in the process of mounting a driving circuit in a non-display area of a display panel.

### BACKGROUND

As the information society develops, the demand for display devices displaying images is increasing, and various types of display devices are utilized such as liquid crystal displays and organic light-emitting displays.

Among display devices, the organic light emitting display device utilizes self-luminous light emitting diodes, which provide fast response speeds and have advantages in contrast ratio, luminous efficiency, brightness, and viewing angle.

The display device may include light emitting diodes arranged in each of a plurality of sub-pixels disposed on a display panel, and may control the brightness of each sub-pixel by controlling a voltage flowing to the light emitting diodes to emit light, thereby displaying images.

The display device may use a structure in which a driving circuit is mounted on a display panel in the form of a chip-on-panel (COP) and connected to the signal lines of the display panel. To this end, a pad may be provided in an area where the driving circuit is mounted to implement electrical contact with the signal lines of the display panel.

In this case, there is a problem in which cracks or damage may frequently occur in the pad due to high pressure during the process of mounting the driving circuit in the non-display area of the display panel.

### SUMMARY

Embodiments of the present disclosure may provide a display device having a structure capable of reducing pad defects in the process of mounting a driving circuit in a non-display area of a display panel.

Embodiments of the present disclosure may provide a display device capable of reducing pad defects by arranging pads and bumps so that bonding pressure points are distributed to a plurality of pads during the process of mounting a driving circuit in a non-display area of a display panel

Embodiments of the present disclosure may provide a display device capable of effectively detecting pad defects by additionally forming a test pad for checking the electrical connection of the pads in a non-display area of the display panel.

The tasks of the embodiments of the present disclosure are not limited to the tasks mentioned in this specification, and other tasks not mentioned will be clearly understood by those skilled in the art from the description below.

Embodiments of the present disclosure may provide a display device including a display panel including a pad area in which a plurality of bonding pads are formed in a non-display area, and a driving circuit including a plurality of bumps electrically coupled to the plurality of bonding pads in the non-display area. The plurality of bonding pads and the plurality of bumps may include a first pad-bump assembly including a first bonding pad and a first bump disposed to fit one end of the first bonding pad, and a second pad-bump assembly including a second bonding pad and a second bump disposed at the center of the second bonding pad. The first pad-bump assembly and the second pad-bump assembly may be alternately arranged in a first direction and a second direction.

According to embodiments of the present disclosure, it is possible to provide a display device having a structure capable of reducing pad defects in the process of mounting a driving circuit in a non-display area of a display panel.

According to embodiments of the present disclosure, it is possible to provide a display device capable of reducing pad defects by arranging pads and bumps so that bonding pressure points are distributed to a plurality of pads during the process of mounting a driving circuit in a non-display area of a display panel

According to embodiments of the present disclosure, it is possible to provide a display device capable of effectively detecting pad defects by additionally forming a test pad for checking the electrical connection of the pads in a non-display area of the display panel.

According to embodiments of the present disclosure, it is possible to provide a display device capable of securing the reliability of the manufacturing process and achieving process optimization through a structure for reducing pad defects.

The effects of the embodiments of the present disclosure are not limited to the effects described in this specification, and other effects not mentioned will be clearly understood by those skilled in the art from the claims.

### BRIEF DESCRIPTION OF THE DRAWINGS

The present disclosure will be more fully understood from the detailed description and accompanying drawings provided below, which are provided for illustration purposes only and are not intended to limit the present disclosure.

FIG. 1 schematically illustrates a display device according to embodiments of the present disclosure.

FIG. 2 illustrates a circuit configuring a sub-pixel in a display device according to embodiments of the present disclosure.

FIG. 3 illustrates a state in which a driving circuit is coupled to a display panel in a chip-on-panel structure in a display device according to embodiments of the present disclosure.

FIG. 4 schematically illustrates an example of a state in which a data driving circuit and a display panel are coupled in a display device according to embodiments of the present disclosure.

FIG. 5 illustrates an example of a case in which a crack occurs in the process of coupling a data driving circuit to a display panel in a display device according to embodiments of the present disclosure.

FIG. 6 illustrates an example of a pad-bump assembly arranged in a display device according to embodiments of the present disclosure.

FIGS. 7A and 7B illustrate examples of a cross-sectional view of a case in which a first pad-bump assembly and a second pad-bump assembly are alternately arranged in a display device according to embodiments of the present disclosure.

FIG. 8 illustrates an example of a case in which a first pad-bump assembly and a second pad-bump assembly are arranged in a zigzag shape in a display device according to embodiments of the present disclosure.

FIG. 9 is a plan view illustrating an example of a case where a floating metal is arranged at the bottom along a pressure line in a display device according to embodiments of the present disclosure.

FIG. 10 is a cross-sectional view illustrating a cross-section cut along line A-B of FIG. 9 and a cross-section of a display area together according to embodiments of the present disclosure.

FIG. 11 illustrates an example of a case where a dummy pad assembly is formed in a bonding pad area in a display device according to embodiments of the present disclosure.

FIG. 12 is a plan view illustrating an example of a dummy pad assembly in a display device according to embodiments of the present disclosure.

FIG. 13 illustrates an example of a cross-sectional view of a dummy pad assembly cut along line C-D of FIG. 12 in a display device according to embodiments of the present disclosure.

### DETAILED DESCRIPTION

Hereinafter, some embodiments of the present disclosure will be described in detail with reference to exemplary drawings. In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the present disclosure will be described in detail with reference to the accompanying drawings.

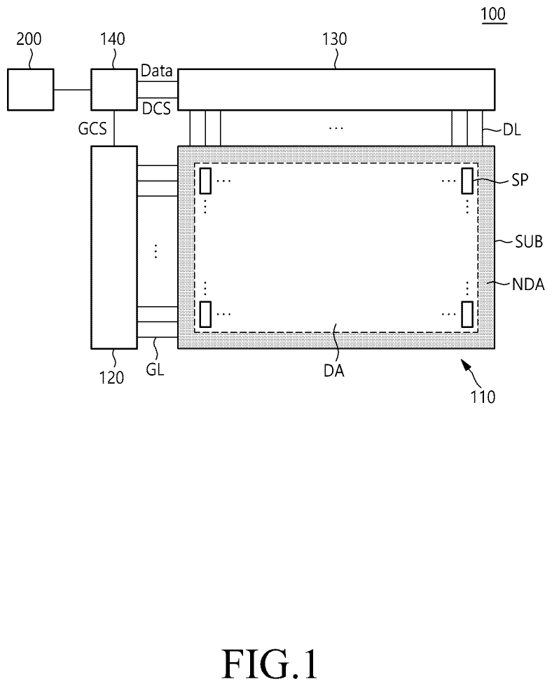

FIG. 1 schematically illustrates a display device according to embodiments of the present disclosure.

Referring to FIG. 1, the display device 100 according to the embodiments of the present disclosure may include a display panel 110 and a display driving circuit for driving the display panel 110.

The display panel 110 may include a display area DA where an image is displayed and a non-display area NDA where an image is not displayed. The non-display area NDA may also be referred to as a bezel area.

The display panel 110 may include a plurality of sub-pixels SP for displaying an image. For example, a plurality of sub-pixels SP may be arranged in the display area DA. In some cases, at least one sub-pixel SP may be arranged in the non-display area NDA. At least one sub-pixel SP arranged in the non-display area NDA may also be referred to as a dummy sub-pixel.

The display panel 110 may include a plurality of signal lines for driving a plurality of sub-pixels SP. For example, the plurality of signal lines may include a plurality of data lines DL and a plurality of gate lines GL. The signal lines may further include a plurality of data lines DL and a plurality of gate lines GL and other signal lines, depending on the structure of the sub-pixel SP. For example, the other signal lines may include a driving voltage line and a reference voltage line.

The plurality of data lines DL and the plurality of gate lines GL may intersect each other. Each of the plurality of data lines DL may be arranged while extending in a first direction. Each of the plurality of gate lines GL may be arranged while extending in a second direction. Here, the first direction may be a column direction and the second direction may be a row direction. In this disclosure, the column direction and the row direction are relative. For example, the column direction may be a vertical direction and the row direction may be a horizontal direction. For another example, the column direction may be a horizontal direction and the row direction may be a vertical direction.

The driving circuit may include a data driving circuit 130 for driving a plurality of data lines DL and a gate driving circuit 120 for driving a plurality of gate lines GL. The driving circuit may further include a timing controller 140 for controlling the data driving circuit 130 and the gate driving circuit 120.

The data driving circuit 130 is a circuit for driving a plurality of data lines DL and may output a data signal (also called a data voltage) corresponding to an image signal to a plurality of data lines DL. The gate driving circuit 120 is a circuit for driving a plurality of gate lines GL, and may generate gate signals and output the gate signals to a plurality of gate lines GL. The gate signal may include one or more scan signals and a light emission signal.

The timing controller 140 may start a scan according to the timing implemented in each frame and control the data driving at an appropriate time according to the scan. The timing controller 140 may convert input image data input from the outside into a data signal format used by the data driving circuit 130, and supply the converted image data Data to the data driving circuit 130.

The timing controller 140 may receive display driving control signals from an external host system 200 along with input image data. For example, the display driving control signals may include a vertical synchronization signal, a horizontal synchronization signal, an input data enable signal, a clock signal, etc.

The timing controller 140 may generate a data driving control signal DCS and a gate driving control signal GCS based on the display driving control signals input from the host system 200. The timing controller 140 may control the driving operation and driving timing of the data driving circuit 130 by supplying the data driving control signal DCS to the data driving circuit 130. The timing controller 140 may control the driving operation and driving timing of the gate driving circuit 120 by supplying a gate driving control signal GCS to the gate driving circuit 120.

The data driving circuit 130 may include one or more source driving integrated circuits SDIC. Each source driving integrated circuit may include a shift register, a latch circuit, a digital to analog converter DAC, and an output buffer. Each source driving integrated circuit may further include an analog to digital converter ADC, depending on the case.

For example, each source driving integrated circuit may be connected to the display panel 110 in a tape-automated-bonding (TAB) manner, may be connected to a bonding pad of the display panel 110 in a chip-on-glass (COG) or chip-on-panel (COP) manner, or implemented in a chip-on-film (COF) manner and connected to the display panel 110.

The gate driving circuit 120 may output a gate signal of a turn-on level voltage or a gate signal of a turn-off level voltage under the control of the timing controller 140. The gate driving circuit 120 may sequentially drive a plurality of gate lines GL by sequentially supplying gate signals of a turn-on level voltage to a plurality of gate lines GL.

The gate driving circuit 120 may include one or more gate driving integrated circuits GDIC.

The gate driving circuit 120 may be connected to the display panel 110 in a tape-automated-bonding (TAB) manner, connected to a bonding pad of the display panel 110 in a chip-on-glass (COG) or chip-on-panel (COP) manner, or connected to the display panel 110 in a chip-on-film (COF) manner. Alternatively, the gate driving circuit 120 may be formed in a non-display area NDA of the display panel 110 in a gate-in-panel (GIP) type. The gate driving circuit 120 may be disposed on or connected to the substrate SUB. That is, the gate driving circuit 120 may be disposed in a non-display area NDA of the substrate SUB in the case of the gate-in-panel (GIP) type. The gate driving circuit 120 may be connected to the substrate SUB if it is a chip-on-glass (COG) type or a chip-on-film (COF) type.

Meanwhile, at least one of the data driving circuit 130 and the gate driving circuit 120 may be disposed in the display area DA. For example, at least one of the data driving circuit 130 and the gate driving circuit 120 may be disposed so as not to overlap with the sub-pixels SP, or may be disposed so as to partially or completely overlap with the sub-pixels SP.

The data driving circuit 130 may be connected to one side (e.g., the upper side or the lower side) of the display panel 110. Depending on the driving method, the panel design method, etc., the data driving circuit 130 may be connected to both sides (e.g., the upper side and the lower side) of the display panel 110, or may be connected to two or more sides among the four sides of the display panel 110.

The gate driving circuit 120 may be connected to one side (e.g., left or right) of the display panel 110. Depending on the driving method, panel design method, etc., the gate driving circuit 120 may be connected to both sides (e.g., left and right) of the display panel 110, or may be connected to two or more of the four sides of the display panel 110.

The timing controller 140 may be implemented as a separate component from the data driving circuit 130, or may be implemented as an integrated circuit by being integrated with the data driving circuit 130. The timing controller 140 may be a controller used in a typical display technology, or may be a control device that can perform other control functions including the timing controller 140, or may be a circuit within the control device. The timing controller 140 may be implemented with various circuits or electronic components such as an integrated circuit (IC), a field programmable gate array (FPGA), an application specific integrated-circuit (ASIC), or a processor.

The timing controller 140 may be mounted on a printed circuit board or a flexible printed circuit, and may be electrically connected to the data driving circuit 130 and the gate driving circuit 120 through the printed circuit board or the flexible printed circuit. The timing controller 140 may transmit and receive signals with the data driving circuit 130 according to one or more predefined interfaces. Here, for example, the interface may include a low voltage differential signaling (LVDS) interface, an EPI interface, a serial peripheral SP interface, etc.

The display device 100 according to the embodiments of the present disclosure may be a self-luminous display device in which the display panel 110 emits light by itself. If the display device 100 according to embodiments of the present disclosure is a self-luminous display device, each of the plurality of sub-pixels SP may include a light emitting element. For example, the display device 100 according to embodiments of the present disclosure may be an organic light-emitting display device in which the light emitting element is implemented as an organic light-emitting diode (OLED). For another example, the display device 100 according to embodiments of the present disclosure may be an inorganic light-emitting display device in which the light emitting element is implemented as an inorganic-based light-emitting diode. For another example, the display device 100 according to embodiments of the present disclosure may be a quantum dot display device in which the light emitting element is implemented as a quantum dot, which is a semiconductor crystal that emits light by itself.

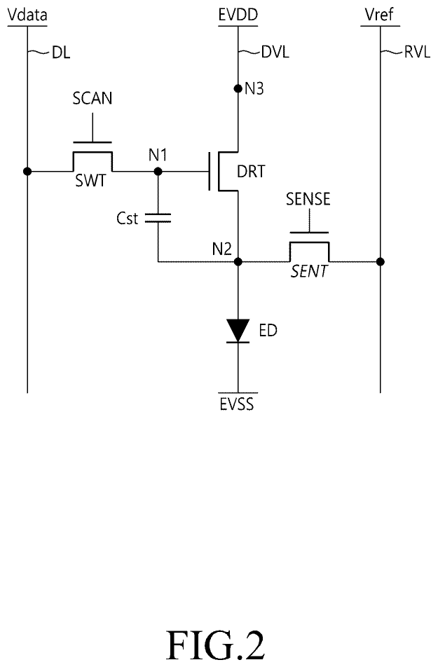

FIG. 2 illustrates an example of a circuit configuring a sub-pixel in a display device according to embodiments of the present disclosure.

Referring to FIG. 2, in a display device 100 according to embodiments of the present disclosure, a sub-pixel SP may include one or more transistors and capacitors, and an organic light-emitting diode may be disposed as a light emitting element ED.

For example, a sub-pixel SP may include a driving transistor DRT, a switching transistor SWT, a sensing transistor SENT, a storage capacitor Cst, and a light emitting element ED.

The driving transistor DRT may have a first node N1, a second node N2, and a third node N3. The first node N1 of the driving transistor DRT may be a gate node to which a data voltage Vdata is applied from a data driving circuit 130 through a data line DL when the switching transistor SWT is turned on. The second node N2 of the driving transistor DRT may be electrically connected to an anode electrode of the light emitting element ED, and may be a source node or a drain node. The third node N3 of the driving transistor DRT may be electrically connected to aa driving voltage line DVL to which a pixel high-potential voltage EVDD is applied, and may be a drain node or a source node.

In this case, during a display driving period, the pixel high-potential voltage EVDD required to display an image may be supplied to the driving voltage line DVL. For example, the pixel high-potential voltage EVDD required to display an image may be 27 V.

The switching transistor SWT may be electrically connected between the first node N1 of the driving transistor DRT and the data line DL, and the gate line GL may be connected to the gate node and operate according to aa scan signal SCAN supplied through the gate line GL. In addition, if the switching transistor SWT is turned on, the data voltage Vdata supplied through the data line DL may be transferred to the gate node of the driving transistor DRT, thereby controlling the operation of the driving transistor DRT.

The sensing transistor SENT may be electrically connected between the second node N2 of the driving transistor DRT and a reference voltage line RVL, and the gate line GL may be connected to the gate node, so that the sensing transistor operates according to a sense signal SENSE supplied through the gate line GL. If the sensing transistor SENT is turned on, a reference voltage Vref for sensing supplied through the reference voltage line RVL may be transferred to the second node N2 of the driving transistor DRT.

That is, by controlling the switching transistor SWT and the sensing transistor SENT, the voltages of the first node N1 and the second node N2 of the driving transistor DRT can be controlled, thereby enabling current to be supplied to drive the light emitting element ED.

The gate nodes of the switching transistor SWT and the sensing transistor SENT may be connected together to one gate line GL, or may be connected to different gate lines GL. Here, a structure in which the switching transistor SWT and the sensing transistor SENT are connected to different gate lines GL is shown as an example, and in this case, the switching transistor SWT and the sensing transistor SENT can be independently controlled by the scan signal SCAN and the sense signal SENSE transmitted through different gate lines GL.

Alternatively, if the switching transistor SWT and the sensing transistor SENT are connected to one gate line GL, the switching transistor SWT and the sensing transistor SENT may be simultaneously controlled by a scan signal SCAN or a sense signal SENSE transmitted through one gate line GL, thereby increasing an aperture ratio of the sub-pixel SP.

Meanwhile, the transistors arranged in the sub-pixel SP may be composed of not only n-type transistors but also p-type transistors, and the case where the transistors are composed of n-type transistors is shown as an example here.

A storage capacitor Cst may be electrically connected between the first node N1 and the second node N2 of the driving transistor DRT, and maintain the data voltage Vdata for one frame.

The storage capacitor Cst may also be connected between the first node N1 and the third node N3 of the driving transistor DRT depending on the type of the driving transistor DRT. The anode electrode of the light emitting element ED may be electrically connected to the second node N2 of the driving transistor DRT, and a pixel low-potential voltage EVSS may be applied to a cathode electrode of the light emitting element ED.

Here, the pixel low-potential voltage EVSS may be a ground voltage or a voltage higher or lower than the ground voltage. In addition, the pixel low-potential voltage EVSS may vary depending on the driving state, and for example, the pixel low-potential voltage EVSS at the display driving time and the pixel low-potential voltage EVSS at the sensing driving time may be set differently from each other. The pixel low-potential voltage EVSS may also be referred to as a base voltage.

The structure of the sub-pixel SP described above as an example is a 3T (Transistor) 1C (Capacitor) structure, and is only an example for explanation, and may further include one or more transistors, or in some cases, one or more capacitors. Alternatively, each of the plurality of sub-pixels SP may have the same structure, or some of the plurality of sub-pixels SP may have different structures.

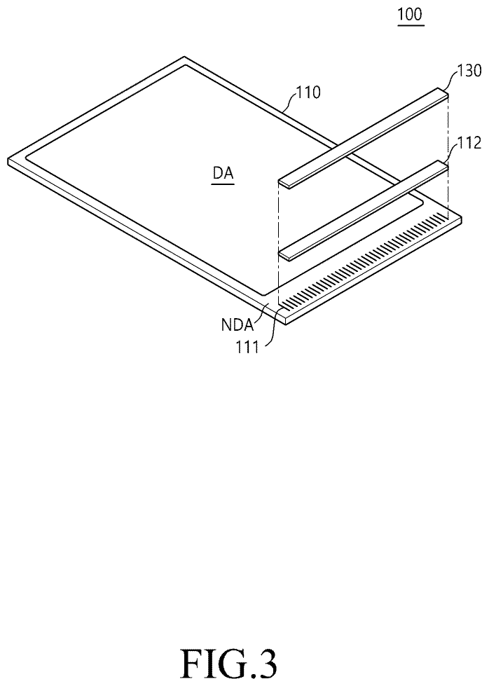

FIG. 3 illustrates a state in which a driving circuit is coupled to a display panel in a chip-on-panel structure in a display device according to embodiments of the present disclosure.

Referring to FIG. 3, in a display device 100 according to the embodiments of the present disclosure, a display panel 110 may include a display area DA where an image is displayed, and a non-display area NDA located outside the display area DA where an image is not displayed.

A gate driving circuit 120 and a data driving circuit 130 may be formed in the non-display area NDA. Here, a case where the data driving circuit 130 is formed in the non-display area NDA of the display panel 110 is illustrated as an example.

A plurality of bonding pads 111 may be formed in the non-display area NDA of the display panel 110 at a position corresponding to the data driving circuit 130. In this case, the area where the plurality of bonding pads 111 are formed may be referred to as a pad area.

The bonding pads 111 may be electrically connected to the data driving circuit 130. The data driving circuit 130 may supply a data voltage to the data line DL formed on the display panel 110 through the bonding pad 111.

That is, a bonding pad 111 may transmit the data voltage output from the data driving circuit 130 to the data line DL of the display panel 110.

In this case, the bonding pad 111 may be electrically connected to an output bump (not shown) of the data driving circuit 130.

A non-conductive film 112 may serve to fix the data driving circuit 130 to the display panel 110 on which the bonding pad 111 is formed.

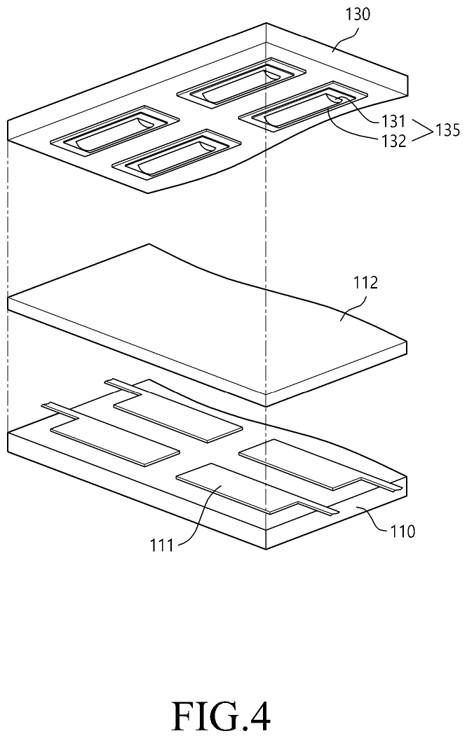

FIG. 4 schematically illustrates an example of a state of coupling between a data driving circuit and a display panel in a display device according to embodiments of the present disclosure.

Referring to FIG. 4, a display device 100 according to embodiments of the present disclosure may have a data driving circuit 130 coupled to a non-display area NDA of a display panel 110.

In this case, in order for the data driving circuit 130 to be coupled to the non-display area NDA of the display panel 110, a plurality of bonding pads 111 may be formed in the non-display area NDA and a plurality of bumps 135 may be formed on one surface of the data driving circuit 130.

The plurality of bumps 135 formed on the data driving circuit 130 may include an elastic support 131 having elasticity and a bump line 132 positioned on an upper portion of the elastic support 131.

The elastic support 131 may be formed of an elastic polymer resin, and the bump line 132 may be formed as a conductive metal layer on the upper portion of the elastic support 131.

The bump line 132 may be electrically connected to the data driving circuit 130, and may transmit a data voltage.

The plurality of bonding pads 111 may be located in the non-display area NDA of the display panel 110 facing the bump 135 formed on the lower portion of the data driving circuit 130. A non-conductive film 112 may be interposed between the bump 135 and the bonding pad 111.

If the data drive circuit 130, the non-conductive film 112 and the display panel 110 are aligned and heated and pressed, the non-conductive film 112 placed between the bump line 132 and the bonding pad 111 may be removed by the pressure, and the bump line 132 and the bonding pad 111 may be electrically connected.

In the process of bonding the data drive circuit 130 and the display panel 110, the non-conductive film 112 having fluidity may move into a space between the bumps 135 and the bumps 135.

In this case, during the process of pressing the data driving circuit 130 onto the display panel 110, a crack may occur in some area of the display panel 110 due to the pressure difference applied to an area where the bump 135 and the bonding pad 111 are located and an area between the bump 135 and the bonding pad 111.

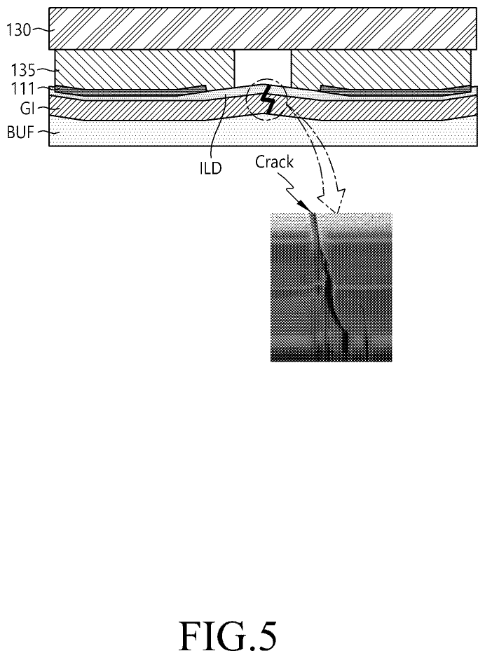

FIG. 5 illustrates an example of a case where a crack occurs during the process of bonding the data driving circuit to the display panel in a display device according to embodiments of the present disclosure.

Referring to FIG. 5, the display device 100 according to embodiments of the present disclosure may have the data driving circuit 130 bonded to the non-display area NDA of the display panel 110 in the form of a chip-on-panel.

In this case, the bump 135 located on the data driving circuit 130 may be arranged to correspond to the bonding pad 111 located on the display panel 110.

In a state where the bump 135 and the bonding pad 111 are arranged to correspond to each other, the data driving circuit 130 may be pressed so that the bump 135 and the bonding pad 111 are in electrical contact.

In this process, a crack may occur in a part corresponding to an area between the bumps 135 due to the difference in pressure transmitted through an area where the bump 135 is located and the pressure transmitted to aa space between the bumps 135.

The crack occurred during coupling the data driving circuit 130 to the display panel 110 may be transmitted to an interlayer insulating film ILD, a gate insulating film GI, and a buffer layer BUF of the display panel 110.

The display device 100 of the present disclosure may provide a structure capable of reducing defects such as cracks that may occur in the process of coupling the data driving circuit 130 to the display panel 110 and detecting defects. Here, the case of coupling the data driving circuit 130 to the display panel 110 is described as an example, but the same may be applied to the process of coupling the gate driving circuit 120 or other driving circuits to the display panel 110.

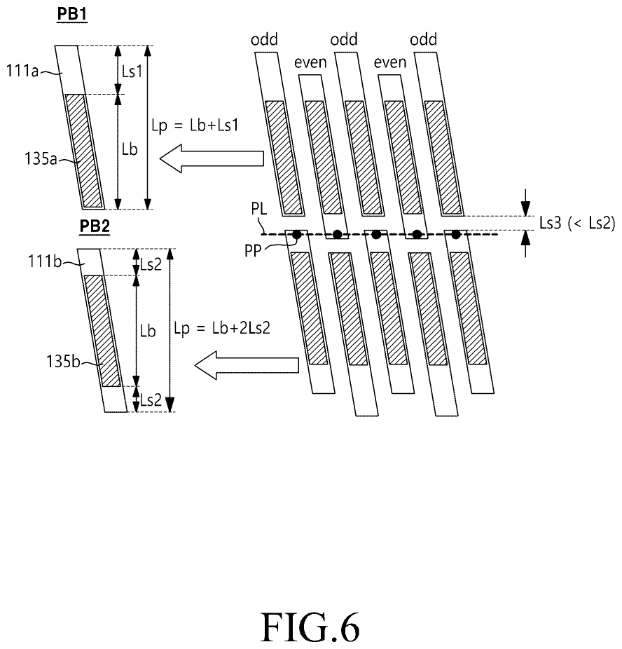

FIG. 6 illustrates an example of a pad-bump assembly formed in a display device according to embodiments of the present disclosure.

Referring to FIG. 6, the display device 100 according to the embodiments of the present disclosure may have a first pad-bump assembly PB1 and a second pad-bump assembly PB2 that are alternately arranged.

The first pad-bump assembly PB1 may include a first bonding pad 111a having a pad length Lp and a first bump 135a having a bump length Lb arranged to match one end of the first bonding pad 111a.

The pad length Lp of the first bonding pad 111a may be greater than the bump length Lb of the first bump 135a. Therefore, the first bonding pad 111a may include an area where the first bump 135a is arranged at one end of the first bonding pad 111a and an area where the first bump 135a is not arranged at the other end.

In the first pad-bump assembly PB1, the area where the first bump 135a is not arranged will have a first separation distance Ls1 that is the pad length Lp minus the bump length Lb. In other words, the pad length Lp of the first bonding pad 111a in the first pad-bump assembly PB1 may be a value obtained by adding the bump length Lb of the first bump 135a and the first separation distance Ls1 (Lp=Lb+Ls1).

Meanwhile, the second pad-bump assembly PB2 may include a second bonding pad 111b having a pad length Lp and a second bump 135b having a bump length Lb arranged at the center of the second bonding pad 111b.

The first bonding pad 111a and the second bonding pad 111b may have the same pad length Lp, and the first bump 135a and the second bump 135b may have the same bump length Lb. In addition, the pad length Lp of the second bonding pad 111b may be greater than the bump length Lb of the second bump 135b.

Therefore, the second bonding pad 111b may include an area where the second bump 135b is arranged in the center of the second bonding pad 111b and an area where the second bump 135b is not arranged on both outer sides of the second bump 135b.

In the second pad-bump assembly PB2, a second separation distance Ls2 may be provided on each side of the second bonding pad 111b where the second bump 135b is not arranged.

The second separation distance Ls2 may correspond to half of the value obtained by subtracting the bump length Lb from the pad length Lp. In other words, the pad length Lp of the second bonding pad 111b in the second pad-bump assembly PB2 may be a value obtained by adding the bump length Lb of the second bump 135b to twice the second separation distance Ls2 (Lp=Lb+2*Ls2).

In the display device 100 of the present disclosure, the first pad-bump assembly PB1 and the second pad-bump assembly PB2 may be alternately arranged along a first direction (e.g., horizontal direction) and a second direction (e.g., vertical direction).

For example, the first pad-bump assembly PB1 may be arranged on an odd-numbered line and the second pad-bump assembly PB2 may be arranged on an even-numbered line based on the first direction.

In addition, the first pad-bump assembly PB1 and the second pad-bump assembly PB2 may be alternately arranged along the second direction.

If the first pad-bump assembly PB1 and the second pad-bump assembly PB2 are alternately arranged, the first bump 135a and the second bump 135b may be arranged to be positioned on the same line in the first direction. In addition, a third separation distance Ls3 between the first pad-bump assembly PB1 and the second pad-bump assembly PB2 along the second direction may be set to be smaller than the second separation distance Ls2.

In this case, the second separation distance Ls2 of the second bonding pad 111b may be set to 50 μm or more, and the third separation distance Ls3 between the first pad-bump assembly PB1 and the second pad-bump assembly PB2 may be set to 30 μm or more.

In this case, since the first bonding pad 111a and the second bonding pad 111b are alternately arranged to overlap in some areas, a pressure line PL may be formed along the overlapping area of the first bonding pad 111a and the second bonding pad 111b.

In this case, during the process of bonding the data drive circuit 130 to the display panel 110, a pressure point PP where the maximum pressure is applied to the display panel 110 may be formed in the center between the first bump 135a and the second bump 135b.

In the display device 100 of the present disclosure, since the second separation distance Ls2 of the second pad-bump assembly PB2 is formed to be greater than the third separation distance Ls3 between the first pad-bump assembly PB1 and the second pad-bump assembly PB2, the pressure point PP may be formed on the upper side of the first bonding pad 111a and the second bonding pad 111b along the pressure line PL. As a result, the pressure applied between the first bonding pad 111a and the second bonding pad 111b can be reduced, thereby reducing an occurrence of a crack.

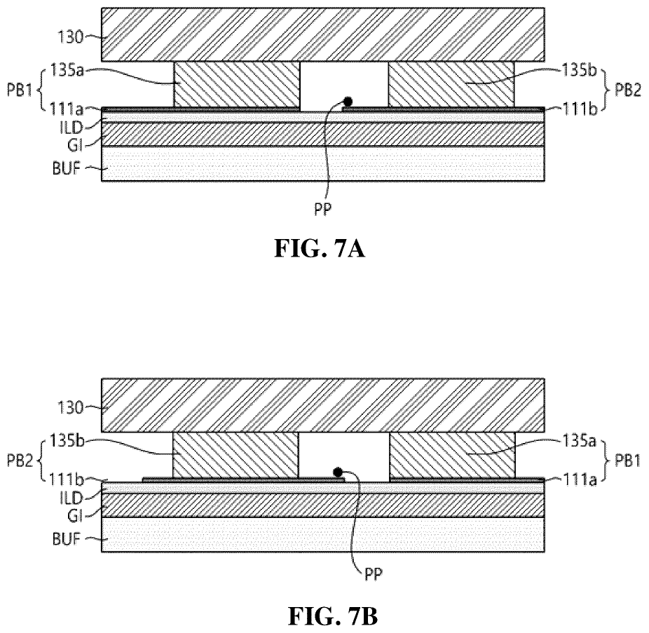

FIGS. 7A and 7B illustrate cross-sectional views of a case where the first pad-bump assembly and the second pad-bump assembly are alternately arranged in the display device according to embodiments of the present disclosure.

Here, FIG. 7A illustrates an example of a pressure point PP formed between the first pad-bump assembly PB1 and the second pad-bump assembly PB2, and FIG. 7B illustrates an example of a pressure point PP formed between the second pad-bump assembly PB2 and the first pad-bump assembly PB1.

Referring to FIG. 7, the second separation distance Ls2 of the area where the second bump 135b is not arranged in the second pad-bump assembly PB2 may be greater than the third separation distance Ls3 between the first pad-bump assembly PB1 and the second pad-bump assembly PB2. Accordingly, the pressure point PP corresponding to the center between the first bump 135a and the second bump 135b is located on the second bonding pad 111b.

As a result, the display device 100 of the present disclosure can reduce cracks by reducing the pressure applied between the first bonding pad 111a and the second bonding pad 111b during the process of bonding the data driving circuit 130 to the display panel 110.

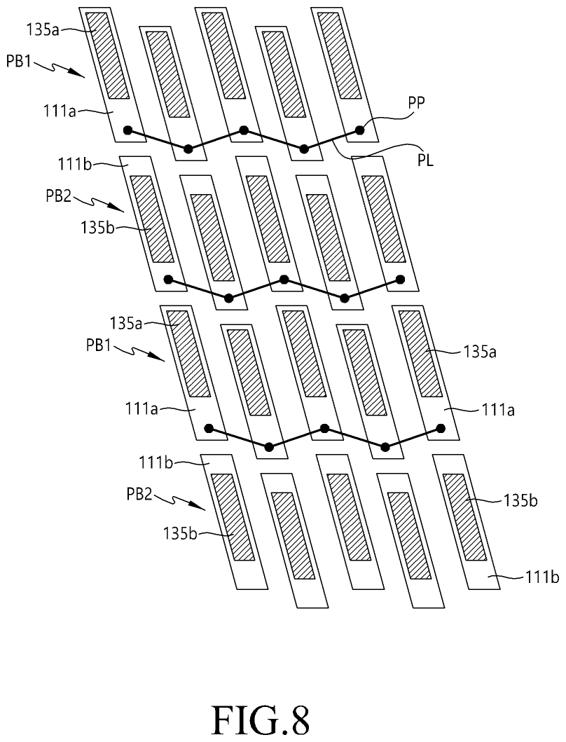

FIG. 8 illustrates an example of a case in which the first pad-bump assembly and the second pad-bump assembly are arranged in a zigzag shape in the display device according to embodiments of the present disclosure.

Referring to FIG. 8, the display device 100 according to the embodiments of the present disclosure may be formed such that a second separation distance Ls2 of a second pad-bump assembly PB2 is larger than a third separation distance Ls3 between the first pad-bump assembly PB1 and the second pad-bump assembly PB2.

Accordingly, in the process of bonding the data driving circuit 130 to the display panel 110, the pressure point PP corresponding to the center between the first bump 135a and the second bump 135b is positioned on the first bonding pad 111a or the second bonding pad 111b.

In this case, since the pressure point PP is located on the first bonding pad 111a or the second bonding pad 111b, it is possible to reduce the pressure applied to the display panel 110 during the process of bonding the data driving circuit 130 to the display panel 110.

Therefore, even if the first pad-bump assembly PB1 and the second pad-bump assembly PB2 are arranged in a zigzag shape, as long as the third separation distance Ls3 between the first pad-bump assembly PB1 and the second pad-bump assembly PB2 is smaller than the second separation distance Ls2 of the second pad-bump assembly PB2, the pressure point PP can be located on the first bonding pad 111a or the second bonding pad 111b.

In this case, the pressure point PP may be also formed in a zigzag shape, and the pressure line PL connecting the pressure point PP will also be formed in a zigzag shape.

In addition, the display device 100 of the present disclosure may reduce the pressure generated in the process of bonding the data driving circuit 130 to the display panel 110 and reduce cracks in the display panel 110 by arranging a floating metal at the bottom along the pressure line PL between the first bump 135a and the second bump 135b.

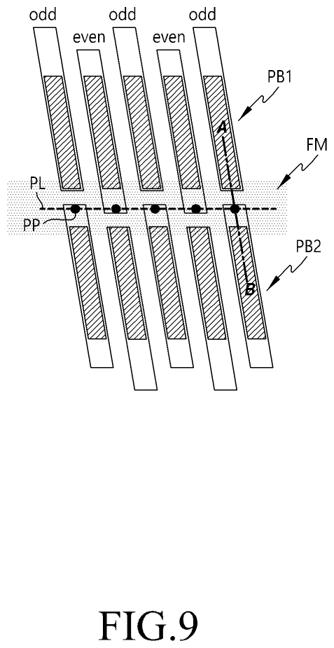

FIG. 9 illustrates a plan view of a case in which the floating metal is arranged at the bottom along the pressure line in the display device according to embodiments of the present disclosure.

Referring to FIG. 9, in the display device 100 of the present disclosure, a floating metal FM may be disposed at the bottom along the pressure line PL between the first bump 135a and the second bump 135b.

In the display device 100 of the present disclosure, a first pad-bump assembly PB1 and a second pad-bump assembly PB2 may be formed so that a pressure point PP located at the center between the first bump 135a and the second bump 135b is positioned on the second bonding pad 111b.

In this case, since a floating metal FM is disposed at the bottom along the pressure line PL between the first bump 135a and the second bump 135b, the pressure generated during the process of bonding the data driving circuit 130 to the display panel 110 can be reduced and cracks in the display panel 110 can be reduced.

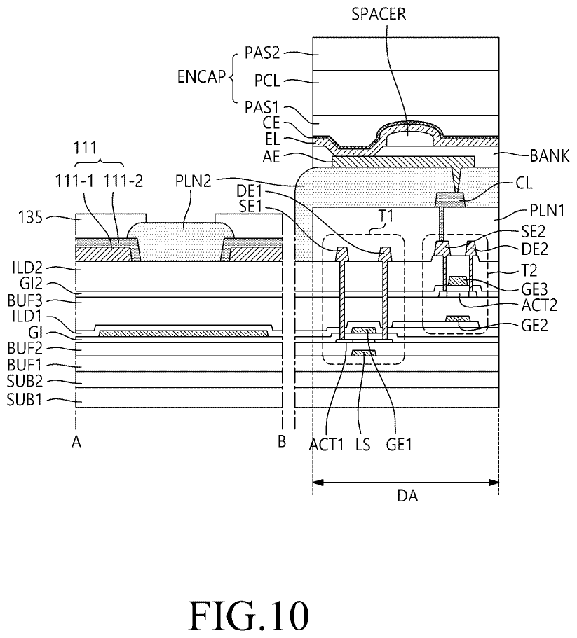

FIG. 10 is a cross-sectional view of a cross-section cut along the A-B line of FIG. 9 and a cross-section of a display area together according to one embodiment.

Referring to FIG. 10, the display device 100 of the present disclosure may include a single substrate or a dual substrate. Here, there is illustrated a case of a dual substrate including a first substrate SUB1 and a second substrate SUB2.

For example, in the case of a single substrate, the substrate may be formed of a polyimide substrate of 10 μm or less.

The first substrate SUB1 and the second substrate SUB2 may be made of polyimide. In addition, if the display panel 110 is formed of a dual substrate SUB1 and SUB2, it is possible to further reduce the pressure during the process of bonding the data driving circuit 130.

In this case, a substrate insulating film may be interposed between the first substrate SUB1 and the second substrate SUB2 of the display area DA. The substrate insulating film may be made of an inorganic film, and may be formed only in the display area DA, and may not be formed in the bending area of the display panel 110. In this way, the substrate SUB in the display area DA is configured with the first substrate SUB1, the substrate insulating film, and the second substrate SUB2, thereby preventing the moisture penetration.

A first buffer layer BUF1 may be formed on a second substrate SUB2.

A light shield layer LS may be formed on the first buffer layer BUF1 to block light in the display area DA.

A second buffer layer BUF2 may be disposed to cover the light shield layer LS.

A first active layer ACT1 constituting a first transistor T1 may be disposed on the second buffer layer BUF2.

The first transistor T1 may include a low-temperature polysilicon transistor among the switching transistors constituting the sub-pixel SP.

A first gate insulating film GI1 may be disposed on the first active layer ACT1.

A floating metal FM and a first gate electrode GE1 made of a gate material may be formed on the first gate insulating film GI1.

The floating metal FM may be formed in a non-display area of the display panel 110, and may provide a function for reducing the pressure applied to the display panel 110 during the process of bonding the data driving circuit 130.

The first gate electrode GE1 may correspond to a gate electrode of the first transistor T1 in the display area DA of the display panel 110.

The gate material may include an opaque conductive material having low resistance, such as aluminum (Al), aluminum alloy (Al alloy), tungsten (W), copper (Cu), nickel (Ni), chromium (Cr), molybdenum (Mo), titanium (Ti), platinum (Pt), or tantalum (Ta). Alternatively, the gate material may be formed as a multilayer structure in which a transparent conductive material such as indium-tin oxide (ITO) or indium-zinc oxide (IZO) and an opaque conductive material are laminated.

A first interlayer insulating film ILD1 may be disposed to cover the first gate electrode GE1.

A second gate electrode GE2 made of a gate material may be formed on the first interlayer insulating film ILD1 of the display area DA.

The second gate electrode GE2 may correspond to a lower gate electrode of a second transistor T2 formed at a position spaced apart from the first transistor T1.

For example, the second transistor T2 may be a driving transistor DRT made of an oxide transistor in a sub-pixel.

In this case, the second transistor T2 may be formed with a dual gate structure including an upper gate electrode and a lower gate electrode. In this case, the second gate electrode GE2 may correspond to the lower gate electrode of the second transistor T2.

A third buffer layer BUF3 may be disposed to cover the second gate electrode GE2 on the first interlayer insulating film ILD1.

A second active layer ACT2 constituting the second transistor T2 may be disposed on the third buffer layer BUF3.

The second active layer ACT2 may constitute an active layer of a driving transistor made of an oxide transistor.

A second gate insulating film GI2 may be disposed to cover the second active layer ACT2.

A third gate electrode GE3 made of a gate material may be formed on the second gate insulating film GI2.

The third gate electrode GE3 may correspond to the upper gate electrode of the second transistor T2.

A second interlayer insulating film ILD2 may be disposed to cover the third gate electrode GE3.

A bonding pad 111 may be formed on the second interlayer insulating film ILD2 of the non-display area. The bonding pad 111 may be formed of a single metal, or may be formed of a dual metal of a first pad layer 111-1 and a second pad layer 111-2. Here, it is illustrated a case where the bonding pad 111 is formed of a dual metal.

A plurality of source-drain electrode patterns may be disposed on the second interlayer insulating film ILD2 of the display area DA.

The source-drain electrode patterns may be formed of any one of molybdenum (Mo), titanium (Ti), tantalum (Ta), tungsten (W), copper (Cu), chromium (Cr), aluminum (Al), and an alloy formed from a combination thereof.

One of the plurality of source-drain electrode patterns may correspond to a first source electrode SE1 and a first drain electrode DE1 of the first transistor T1. In addition, another of the plurality of source-drain electrode patterns may correspond to a second source electrode SE2 and a second drain electrode DE2 of the second transistor T2.

A portion of the source-drain electrode pattern may be electrically connected to the second active layer ACT2 of the second transistor T2 through a contact hole of the second interlayer insulating film ILD2 and the second gate insulating film GI2.

In addition, another portion of the source-drain electrode pattern may be electrically connected to the first active layer ACT1 of the first transistor T1 through a contact hole of the second interlayer insulating film ILD2, the second gate insulating film GI2, the third buffer layer BUF3, the first interlayer insulating film ILD1, and the first gate insulating film GI1.

The source-drain electrode pattern may form the first pad layer 111-1 of the non-display area.

A first planarization layer PLN1 may be disposed to cover the source-drain electrode pattern in the display area DA. The first planarization layer PLN1 may be made of an organic insulating material such as an acrylic resin. In this case, the driving transistor DRT and some switching transistors constituting the sub-pixel SP may be formed as a dual gate structure including an upper gate electrode and a lower gate electrode to improve the current characteristics in the turn-on state and secure reliability.

A connection electrode pattern may be disposed on the first planarization layer PLN1.

The connection electrode pattern of the display area DA may form a connection line CL electrically connected to the second source electrode SE2 of the second transistor T2 through aa contact hole of the first planarization layer PLN1.

The connection electrode pattern of the non-display area may form a second pad layer 111-2 of the bonding pad 111. The second pad layer 111-2 may be formed to cover the first pad layer 111-1.

A second planarization layer PLN2 may be disposed to cover a portion of the bonding pad 111 formed in the non-display area and the connection line CL of the display area DA.

In the non-display area, the second planarization layer PLN2 may be opened so that a portion of the bonding pad 111 is exposed, thereby forming an electrical connection portion between the bonding pad 111 and a bump 135. The second planarization layer PLN2 formed between the bonding pads 111 may prevent electrical contact between the bonding pads 111.

The first planarization layer PLN1 and the second planarization layer PLN2 may be made of an organic insulating material such as an acrylic resin.

A light emitting element ED may be disposed on the second planarization layer PLN2.

The light emitting element ED may include an anode electrode AE, an emission layer EL, and a cathode electrode CE.

The anode electrode AE may be disposed on a second planarization layer PLN2. The anode electrode AE may be electrically connected to the connection line CL through a contact hole of the second planarization layer PLN2.

A bank BANK may be disposed while covering a portion of the anode electrode AE. A portion of the bank BANK corresponding to an emission area of the sub-pixel SP may be open.

A spacer SPACER may be disposed on a portion of the bank BANK.

A portion of the anode electrode AE may be exposed to an opening (or open portion) of the bank BANK.

The emission layer EL may be located on the side of the bank BANK and the opening (or open portion) of the bank BANK. All or part of the emission layer EL may be located between adjacent banks BANK. The emission layer EL may include an organic film.

The emission layer EL may be in contact with the anode electrode AE at the opening of the bank BANK. A cathode electrode CE may be disposed on the emission layer EL.

An encapsulation layer ENCAP may be disposed on the light emitting element ED in the display area DA.

The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest. Accordingly, the second encapsulation layer PCL may function as a planarization layer.

The first encapsulation layer PAS1 may be also referred to as a first inorganic encapsulation layer, the second encapsulation layer PCL may be also referred to as an organic encapsulation layer, and the third encapsulation layer PAS2 may be also referred to as a second inorganic encapsulation layer.

The first encapsulation layer PAS1 may be disposed on the cathode electrode CE, and may be disposed closest to the light emitting element ED. The first encapsulation layer PAS1 may be formed of an inorganic insulating material capable of low-temperature deposition. For example, the first encapsulation layer PAS1 may be formed of silicon nitride (SiNx), silicon oxide (SiOx), silicon oxynitride (SiON), or aluminum oxide (Al2O3). Since the first encapsulation layer PAS1 is deposited in a low-temperature atmosphere, the first encapsulation layer PAS1 may prevent the emission layer EL including an organic material vulnerable to a high-temperature atmosphere from being damaged during the deposition process.

The second encapsulation layer PCL may be formed with a smaller area than the first encapsulation layer PAS1. In this case, the second encapsulation layer PCL may be formed to expose both ends of the first encapsulation layer PAS1. The second encapsulation layer PCL may act as a buffer to relieve stress between each layer due to the bending of the display device 100 and may also act to enhance the flattening performance.

For example, the second encapsulation layer PCL may be formed of an acrylic resin, an epoxy resin, a polyimide, polyethylene, or silicon oxycarbon (SiOC), and may be formed of an organic insulating material. For example, the second encapsulation layer PCL may be formed by an inkjet method.

The third encapsulation layer PAS2 may be formed on the second encapsulation layer PCL to cover an upper surface and side surfaces of each of the second encapsulation layer PCL and the first encapsulation layer PAS1. The third encapsulation layer PAS2 may minimize or block external moisture or oxygen from penetrating into the first encapsulation layer PAS1 and the second encapsulation layer PCL.

For example, the third encapsulation layer PAS2 may be formed of an inorganic insulating material such as silicon nitride (SiNx), silicon oxide (SiOx), silicon oxynitride (SiON), or aluminum oxide (Al2O3).

In addition, the display device 100 of the present disclosure may form a dummy pad assembly that is not electrically connected to the data driving circuit 130 in some areas of the area where the bonding pad 111 is arranged, and may detect a defect on the bonding pad 111 by using the dummy pad assembly.

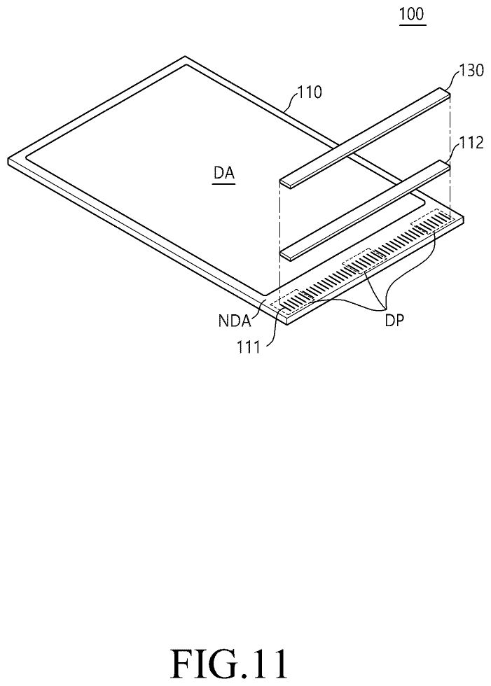

FIG. 11 illustrates an example of a case where a dummy pad assembly is formed in a bonding pad area in a display device according to embodiments of the present disclosure.

Referring to FIG. 11, in the display device 100 according to embodiments of the present disclosure, a plurality of bonding pads 111 may be formed in a non-display area NDA of the display panel 110 at a position corresponding to the data driving circuit 130. In this case, the area where the plurality of bonding pads 111 are formed may be referred to as a pad area.

The bonding pad 111 may be electrically connected to the data driving circuit 130. The data driving circuit 130 may supply a data voltage to the data line DL formed on the display panel 110 through the bonding pad 111. That is, the bonding pad 111 may transmit the data voltage output from the data driving circuit 130 to the data line DL of the display panel 110.

In this case, the bonding pad 111 may be electrically connected to an output bump (not shown) of the data driving circuit 130. A non-conductive film 112 may serve to fix the data driving circuit 130 to the display panel 110 on which the bonding pad 111 is formed.

In addition, a dummy pad assembly DP that is not electrically connected to the data driving circuit 130 may be formed in at least a part of the pad area.

The dummy pad assembly DP may be a pad for detecting a defect such as a crack in the bonding pad 111 during the process of bonding the data driving circuit 130 to the display panel 110.

The dummy pad assembly DP may be disposed in a plurality of areas among the pad areas. For example, three dummy pad assemblies DP may be formed at both ends of the pad area and in a central area of the pad area.

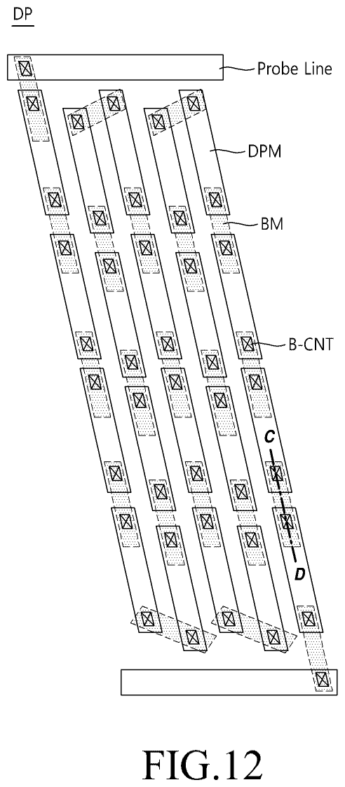

FIG. 12 is a plan view illustrating an example of a dummy pad assembly in a display device according to embodiments of the present disclosure.

Referring to FIG. 12, in the display device 100 according to embodiments of the present disclosure, a dummy pad assembly DP that is not electrically connected to the data driving circuit 130 may be formed in some areas among the areas where the bonding pad 111 is disposed in the non-display area of the display panel 110.

The dummy pad assembly DP may include a dummy pad metal DPM, a bridge metal BM, and a probe line.

The dummy pad metal DPM may be disposed in a form corresponding to a bonding pad 111 that is electrically connected to the data driving circuit 130. That is, the dummy pad metal DPM may be arranged in the same size and arrangement as the bonding pad 111, except that the dummy pad metal is not electrically connected to the data driving circuit 130.

The bridge metal BM may be a metal layer for electrically connecting the dummy pad metals DPM. The bridge metal BM may be electrically connected to the dummy pad metal DPM through a bridge contact hole B-CNT.

Specifically, the bridge metal BM may be electrically connected to the dummy pad metal through a bridge contact hole B-CNT formed at the end of the dummy pad metal DPM that is vertically adjacent to each other.

In this case, the bridge metal BM may electrically connect all dummy pad metals DPM included in one dummy pad assembly DP, and may be connected to the probe lines located at the top and bottom.

The probe line may be a metal line for detecting cracks or short circuits in the dummy pad metal DPM electrically connected through the bridge metal BM. The probe line may be arranged on both sides of the dummy pad metal DPM to detect the electrical characteristics of the dummy pad metal DPM.

In one dummy pad assembly DP, all dummy pad metals DPM may be connected through the bridge metal BM, and electrical characteristics may be detected through a pair of probe lines.

For example, if three dummy pad assemblies DP are formed in a pad area, the electrical characteristics of the three dummy pad assemblies DP may be detected respectively through three pairs of probe lines.

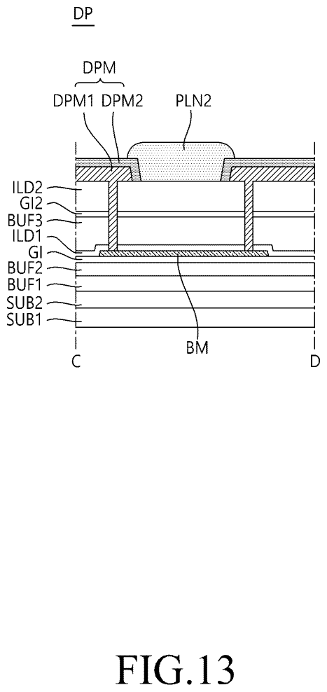

FIG. 13 is a cross-sectional view of a dummy pad assembly cut along the C-D line of FIG. 12 in a display device according to embodiments of the present disclosure.

Referring to FIG. 13, the display panel 110 of the display device 100 of the present disclosure may include a first substrate SUB1 and a second substrate SUB2.

The first substrate SUB1 and the second substrate SUB2 may be made of polyimide. If the display panel 110 is formed as a dual substrate SUB1 and SUB2, it is possible to further alleviate the pressure during the process of bonding the data driving circuit 130.

A first buffer layer BUF1 and a second buffer layer BUF2 may be disposed on a second substrate SUB2.

A first gate insulating film GI1 may be disposed on the second buffer layer BUF2. The first gate insulating film GI1 may be formed of a material that covers a first active layer constituting a first transistor T1 of a display area DA.

A bridge metal BM made of a gate material may be formed on the first gate insulating film GI1.

The bridge metal BM may electrically connect a dummy pad metal DPM formed on the upper side.

The bridge metal BM may be formed of an opaque conductive material having low resistance, such as aluminum (Al), aluminum alloy (Al alloy), tungsten (W), copper (Cu), nickel (Ni), chromium (Cr), molybdenum (Mo), titanium (Ti), platinum (Pt), or tantalum (Ta). Alternatively, the gate material may be formed as a multi-layer structure in which a transparent conductive material such as indium-tin oxide (ITO) or indium-zinc oxide (IZO) and an opaque conductive material are laminated.

A first interlayer insulating film ILD1 may be disposed to cover the bridge metal BM.

A third buffer layer BUF3 may be disposed to cover the first interlayer insulating film ILD1.

A second gate insulating film GI2 may be disposed to cover the third buffer layer BUF3.

The second gate insulating film GI2 may be formed of a material covering the second active layer constituting the second transistor T2 of the display area DA.

A second interlayer insulating film ILD2 may be disposed while covering the second gate insulating film GI2.

A dummy pad metal DPM may be formed on the second interlayer insulating film ILD2. The dummy pad metal DPM may be formed of a single metal, or may be formed of a dual metal of a first dummy pad metal DPM1 and a second dummy pad metal DPM2. Here, it is exemplified a case where the dummy pad metal DPM is formed of a dual metal.

The dummy pad metal DPM may be electrically connected to a lower bridge metal BM through a bridge contact hole penetrating the second interlayer insulating film ILD2, the second gate insulating film GI2, the third buffer layer BUF3, and the first interlayer insulating film ILD1.

Therefore, a plurality of dummy pad metals DPM forming the dummy pad assembly DP may be electrically connected through the bridge metal BM.

A first planarization layer PLN2 may be disposed to cover a portion of the dummy pad metal DPM.

A second planarization layer PLN2 may be opened to expose a portion of the dummy pad metal DPM to form an electrical connection portion with the data driving circuit 130.

In this way, in the display device 100 of the present disclosure, a dummy pad metal DPM having the same structure as the bonding pad 111 may be formed in a portion of the pad area, so that it is possible to detect whether the bonding pad 111 is defective by detecting a defect in the dummy pad assembly DP formed in a portion of the pad area.

The display device according to the embodiments of the present disclosure may be described as follows.

A display device according to the embodiments of the present disclosure may include a display panel including a pad area in which a plurality of bonding pads are formed in a non-display area, and a driving circuit including a plurality of bumps electrically coupled to the plurality of bonding pads in the non-display area. The plurality of bonding pads and the plurality of bumps may include a first pad-bump assembly including a first bonding pad and a first bump disposed to fit one end of the first bonding pad, and a second pad-bump assembly including a second bonding pad and a second bump disposed at the center of the second bonding pad. In this case, the first pad-bump assembly and the second pad-bump assembly may be alternately arranged in a first direction and a second direction.

The first pad-bump assembly may include a first separation distance along the second direction at one side of the first bonding pad at which the first bump is not disposed, and the second pad-bump assembly may include a second separation distance along the second direction at both sides of the second bonding pad at which the second bump is not disposed. A third separation distance between the first pad-bump assembly and the second pad-bump assembly along the second direction may be smaller than the second separation distance.

The second separation distance may be 50 μm or more, and the third separation distance may be 30 μm or more.

The first bump and the second bump may be arranged at the same position along the first direction, and the first bonding pad and the second bonding pad may be arranged in a zigzag shape along the first direction.

A pressure point between the first bump and the second bump with respect to the second direction may be located on the second bonding pad.

The first bump and the second bump may be arranged in a zigzag shape along the first direction, and the first bonding pad and the second bonding pad may be arranged in a zigzag shape along the first direction. A pressure point between the first bump and the second bump with respect to the second direction may be located on the second bonding pad.

The display device according to the embodiments of the present disclosure may further include a floating metal formed along an area where a pressure point between the first bump and the second bump is formed with respect to the second direction

The floating metal may be formed as a gate material of a transistor formed in a display area of the display panel.

The first bonding pad and the second bonding pad may include a first pad layer, and a second pad layer formed to cover the first pad layer.

The pad area may further include one or more dummy pad assembly that is not electrically connected to the driving circuit.

The one or more dummy pad assembly may include a first dummy pad assembly located at a first side end of the pad area, a second dummy pad assembly located at an opposite end of the first side end in the pad area, and a third dummy pad assembly located between the first dummy pad assembly and the second dummy pad assembly.

The one or more dummy pad assembly may include a plurality of dummy pad metals, a bridge metal electrically connecting the plurality of dummy pad metals, and a pair of probe lines located at both ends of the plurality of dummy pad metals.

The plurality of dummy pad metals may be formed with the same size and the same arrangement as the plurality of bonding pads.

The bridge metal may be formed as a gate material of a transistor formed in a display area of the display panel.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A display device comprising:
a display panel including a pad area in which a plurality of bonding pads are positoned in a non-display area; and
a driving circuit including a plurality of bumps, the plurality of bumps electrically coupled to the plurality of bonding pads in the non-display area,
wherein the plurality of bonding pads and the plurality of bumps comprise:
a first pad-bump assembly including a first bonding pad and a first bump that fits one end of the first bonding pad, and
a second pad-bump assembly including a second bonding pad and a second bump disposed at a center of the second bonding pad,
wherein the first pad-bump assembly and the second pad-bump assembly are alternately arranged in a first direction and a second direction.

2. The display device of claim 1, wherein the first pad-bump assembly includes a first separation distance along the second direction at one side of the first bonding pad at which the first bump is not disposed,
wherein the second pad-bump assembly includes a second separation distance along the second direction at both sides of the second bonding pad at which the second bump is not disposed,
wherein a third separation distance between the first pad-bump assembly and the second pad-bump assembly along the second direction is smaller than the second separation distance.

3. The display device of claim 2, wherein the second separation distance is 50 μm or more and the third separation distance is 30 μm or more.

4. The display device of claim 1, wherein the first bump and the second bump are arranged at a same position along the first direction,
wherein the first bonding pad and the second bonding pad are arranged in a zigzag shape along the first direction.

5. The display device of claim 4, wherein a pressure point between the first bump and the second bump, which are adjacent in the second direction, is located on the second bonding pad.

6. The display device of claim 5, wherein the pressure point is located on a straight line in the first direction.

7. The display device of claim 1, wherein the first bump and the second bump are arranged in a zigzag shape along the first direction, respectively,
wherein the first bonding pad and the second bonding pad are arranged in a zigzag shape along the first direction, respectively,
wherein pressure points between the first bump and the second bump adjacent in the second direction are located on the first bonding pad and the second bonding pad.

8. The display device of claim 7, wherein the pressure points are arranged in a zigzag shape in the first direction.

9. The display device of claim 1, further comprising:
a floating metal disposed along an area where a pressure point between the first bump and the second bump is formed with respect to the second direction.

10. The display device of claim 9, wherein the floating metal includes a gate material of a transistor that is disposed in a display area of the display panel.

11. The display device of claim 1, wherein the first bonding pad and the second bonding pad include a first pad layer and a second pad layer that covers the first pad layer.

12. The display device of claim 1, wherein the pad area further includes one or more dummy pad assemblies that are not electrically connected to the driving circuit.

13. The display device of claim 12, wherein the one or more dummy pad assemblies include:
a first dummy pad assembly located at a first side end of the pad area;
a second dummy pad assembly located at an opposite end of the first side end in the pad area; and
a third dummy pad assembly located between the first dummy pad assembly and the second dummy pad assembly.

14. The display device of claim 12, wherein the one or more dummy pad assemblies include:
a plurality of dummy pad metals;
a bridge metal electrically connecting the plurality of dummy pad metals; and
a pair of probe lines located at both ends of the plurality of dummy pad metals.

15. The display device of claim 14, wherein the plurality of dummy pad metals have a same size and a same arrangement as the plurality of bonding pads.

16. The display device of claim 14, wherein the bridge metal inclues a gate material of a transistor that is disposed in a display area of the display panel.

17. The display device of claim 14, wherein the bridge metal is electrically connected through a bridge contact hole located at an end of two dummy pad metals adjacent to each other in the second direction.

18. The display device of claim 14, wherein the bridge metal electrically connects all the plurality of dummy pad metals included in one dummy pad assembly.
